(19) United States
(12) Patent Application Publication
(10) Pub. No.: US 2025/0364043 A1
(43) Pub. Date: Nov. 27, 2025

(54) SEMICONDUCTOR MEMORY DEVICE

(71) Applicant: Socionext Inc., Kanagawa (JP)

(72) Inventor: Shinichi MORIWAKI, Yokohama-shi (JP)

(21) Appl. No.: 19/291,054

(22) Filed: Aug. 5, 2025

Related U.S. Application Data
(63) Continuation of application No. PCT/JP2024/007782, filed on Mar. 1, 2024.

(30) Foreign Application Priority Data
Mar. 8, 2023 (JP) 2023-035904

(51) Int. Cl. G11C 11/419; G11C 11/412; H10B 10/00

(52) U.S. Cl. CPC G11C 11/419; G11C 11/412; H10B 10/12; H10B 10/18

(57) ABSTRACT

A semiconductor memory device includes memory cells and a write circuit. Each of the memory cells includes p-type drive transistors, n-type load transistors, and p-type access transistors connected to a bit line pair. The write circuit includes a column selection circuit including p-type transistors and a predischarge circuit including n-type transistors.

### CROSS-REFERENCE TO RELATED APPLICATIONS

This is a continuation of International Application No. PCT/JP2024/007782 filed on Mar. 1, 2024, which claims priority to Japanese Patent Application No. 2023-035904 filed on Mar. 8, 2023. The entire disclosures of these applications are incorporated by reference herein.

### BACKGROUND

The present disclosure relates to a semiconductor memory device, more particularly to a static random access memory (SRAM).

The SRAM is widely used as one type of major memories incorporated in a semiconductor integrated circuit device.

Conventionally, as described in Japanese Unexamined Patent Publication No. 2009-176407, for example, a semiconductor memory device in which a transfer gate (access transistor), among transistors constituting an SRAM cell, is formed of a p-type transistor is disclosed.

In conventional techniques including the cited patent document, however, while a circuit diagram of a memory cell having a transfer gate formed of a p-type transistor is shown, a peripheral circuit of an SRAM using such a memory cell has not been disclosed.

An objective of the present disclosure is presenting a peripheral circuit of an SRAM using an SRAM cell that uses a p-type transistor for an access transistor, particularly a circuit related to write of the SRAM.

### SUMMARY

According to the first mode of the disclosure, a semiconductor memory device includes memory cells and a write circuit, wherein each of the memory cells includes a first p-type transistor having a gate connected to a first node, a source connected to a first power supply, and a drain connected to a second node, a first n-type transistor having a gate connected to the first node, a source connected to a second power supply, and a drain connected to the second node, a second p-type transistor having a gate connected to the second node, a source connected to the first power supply, and a drain connected to the first node, a second n-type transistor having a gate connected to the second node, a source connected to the second power supply, and a drain connected to the first node, a third p-type transistor provided between the second node and a first bit line, and having a gate connected to a word line, and a fourth p-type transistor provided between the first node and a second bit line, and having a gate connected to the word line, and the write circuit includes a column selection circuit including a fifth p-type transistor provided between the first bit line and the first power supply and a sixth p-type transistor provided between the second bit line and the first power supply, and a predischarge circuit including a third n-type transistor provided between the first bit line and the second power supply and a fourth n-type transistor provided between the second bit line and the second power supply.

According to the present disclosure, a peripheral circuit of an SRAM using an SRAM cell that uses a p-type transistor for an access transistor is provided.

### BRIEF DESCRIPTION OF THE DRAWINGS

FIG. 1 is a view showing a configuration example of a memory cell array constituting a semiconductor memory device according to the first embodiment.

FIG. 2 is a view showing a configuration example of a write circuit constituting the semiconductor memory device according to the first embodiment.

FIG. 3 is a timing chart showing an operation example of the semiconductor memory device according to the first embodiment.

FIG. 4 is a view showing an alteration of the memory cell array according to the first embodiment.

FIG. 5 is a view showing an alteration of the write circuit according to the first embodiment.

FIG. 6 is a view showing a configuration example of a write circuit constituting a semiconductor memory device according to the second embodiment.

FIG. 7 is a timing chart showing an operation example of the semiconductor memory device according to the second embodiment.

FIG. 8 is a view for explaining a write assist operation of the semiconductor memory device according to the second embodiment.

FIG. 9 is a view showing an alteration of the write circuit according to the second embodiment.

FIG. 10 is a view showing a configuration example of a memory cell array constituting a semiconductor memory device according to the third embodiment.

FIG. 11 is a view showing a configuration example of a write circuit constituting the semiconductor memory device according to the third embodiment.

FIG. 12 is a timing chart showing an operation example of the semiconductor memory device according to the third embodiment.

FIG. 13 is a view for explaining a write assist operation of the semiconductor memory device according to the third embodiment.

FIG. 14 is a view showing an alteration of the memory cell array according to the third embodiment.

FIG. 15 is a view showing an alteration of the write circuit according to the third embodiment.

### DETAILED DESCRIPTION

Embodiments of the present disclosure will be described hereinafter with reference to the accompanying drawings. Note that a signal line (node) and a signal passing through the signal line (node) may be described using the same reference character. Similarly, a power supply node and a voltage supplied to the power supply node may be described using the same reference character. Also, in the present disclosure, the term “connection” is used as a concept including the case that components are mutually connected indirectly via an element such as a transistor, in addition to the case that components are mutually connected directly.

### First Embodiment

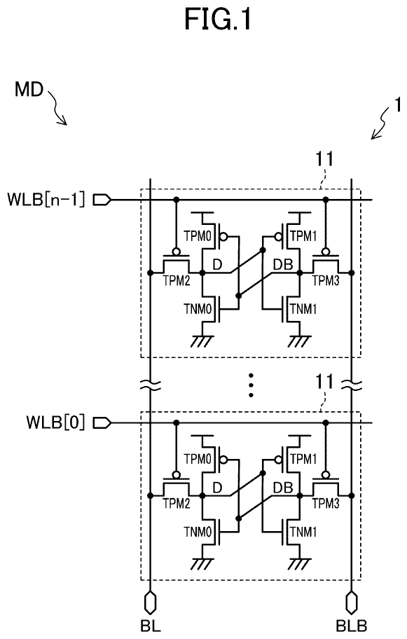

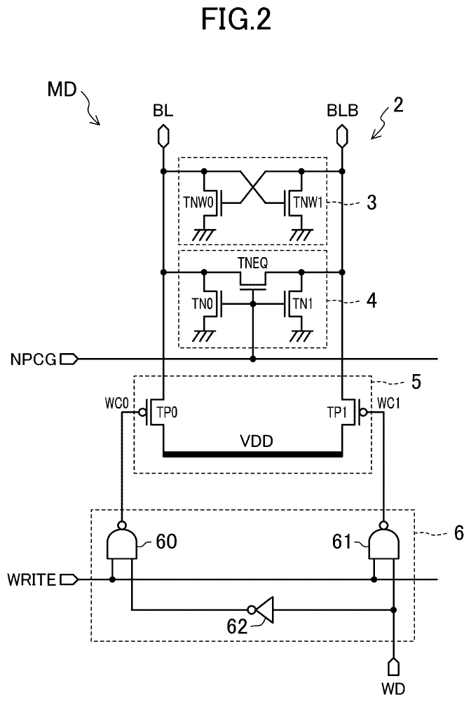

FIGS. 1 and 2 show a configuration example of a semiconductor memory device MD according to this embodiment. The semiconductor memory device MD of this embodiment, which is a single-column device, includes a memory cell array 1 shown in FIG. 1 and a write circuit 2 shown in FIG. 2.

### [Memory Cell Array]

In this embodiment, the memory cell array 1 includes a plurality of memory cells 11 arranged in an array of n rows (n is a natural number)×m sets (m is a natural number). The memory cells 11 in each row are connected to a corresponding one of word lines WLB[0] to WLB[n−1]. In other words, in this example, the memory cell array 1 is constituted by n word lines WLB[0] to WLB[n−1] and n×m memory cells 11. In FIG. 1, one set out of the m sets of memory cells 11 is shown. In the following description, when the word lines WLB[0] to WLB[n−1] are mentioned with no distinction among them, they may be referred to as the “word lines WLB” simply.

### [Memory Cell]

The memory cell 11 includes p-type drive transistors TPM0 and TPM1, n-type load transistors TNM0 and TNM1, and p-type access transistors TPM2 and TPM3.

In the drive transistor TPM0 (corresponding to the first p-type transistor), the gate is connected to a node DB (corresponding to the first node), the source is connected to the power supply VDD (corresponding to the first power supply), and the drain is connected to a node D (corresponding to the second node). In the load transistor TNM0 (corresponding to the first n-type transistor), the gate is connected to the node DB, the source is connected to the ground VSS (corresponding to the second power supply), and the drain is connected to the node D. That is, the drive transistor TPM0 and the load transistor TNM0 are serially connected between the power supply VDD and the ground VSS.

In the drive transistor TPM1 (corresponding to the second p-type transistor), the gate is connected to the node D, the source is connected to the power supply VDD, and the drain is connected to the node DB. In the load transistor TNM1 (corresponding to the second n-type transistor), the gate is connected to the node D, the source is connected to the ground VSS, and the drain is connected to the node DB. That is, the drive transistor TPM1 and the load transistor TNM1 are serially connected between the power supply VDD and the ground VSS. Also, a latch is formed by the drive transistors TPM0 and TPM1 and the load transistors TNM0 and TNM1.

The access transistor TPM2 (corresponding to the third p-type transistor) is provided between the node D and a bit line BL (corresponding to the first bit line) and has a gate connected to the word line WLB. The access transistor TPM3 (corresponding to the fourth p-type transistor) is provided between the node DB and a bit line BLB (corresponding to the second bit line) and has a gate connected to the word line WLB. Note that, in the following description, the pair of the bit line BL and the bit line BLB may be called the “bit line pair BL, BLB.”

### [Write Circuit]

The write circuit 2 shown in FIG. 2 is connected to the bit line pair BL, BLB of the memory cell array 1. The write circuit 2 is provided for each of the sets in the memory cell array 1. That is, in this example, m write circuits 2 are provided for the m sets of memory cells 11. In FIG. 2, one write circuit 2 is illustrated as an example.

The write circuit 2 includes a pulldown circuit 3, a predischarge circuit 4, a column selection circuit 5, and a write driver 6.

### [Pulldown Circuit]

When one bit line of the bit line pair BL, BLB is ‘H’ (High level), the pulldown circuit 3 pulls down the other bit line to ‘L’ (Low level). Hereinafter, a signal of High level will be simply expressed as ‘H’, and a signal of Low level will be simply expressed as ‘L’.

In this example, the pulldown circuit 3 includes n-type transistors TNW0 and TNW1. The transistor TNW0 is provided between the bit line BL and the ground VSS and has a gate connected to the bit line BLB. The transistor TNW1 is provided between the bit line BLB and the ground VSS and has a gate connected to the bit line BL.

### [Predischarge Circuit]

The predischarge circuit 4 includes n-type transistors TNEQ, TN0, and TN1. The transistor TNEQ (corresponding to the fifth n-type transistor) is provided between the bit line BL and the bit line BLB. The transistor TN0 (corresponding to the third n-type transistor) is provided between the bit line BL and the ground VSS. The transistor TN1 (corresponding to the fourth n-type transistor) is provided between the bit line BLB and the ground VSS. A predischarge control signal NPCG is given to the gates of the transistors TNEQ, TN0, and TN1.

In the predischarge circuit 4, when the predischarge control signal NPCG becomes ‘H’ while the memory cell 11 is in an inactive state, the transistors TN0 and TN1 are turned ON to discharge the bit line pair BL, BLB to ‘L’.

### [Column Selection Circuit]

The column selection circuit 5 includes p-type transistors TP0 and TP1. The transistor TP0 (corresponding to the fifth p-type transistor) is provided between the power supply VDD and the bit line BL, and an output signal WC0 of the write driver 6 is given to its gate. The transistor TP1 (corresponding to the sixth p-type transistor) is provided between the power supply VDD and the bit line BLB, and an output signal WC1 of the write driver 6 is given to its gate.

In the column selection circuit 5, one of the transistors TP0 and TP1 is turned ON based on the output signals WC0 and WC1 of the write driver 6, to select the bit line (BL or BLB) that is to be the write target.

### [Write Driver]

The write driver 6 enters the write state when a write control signal WRITE becomes ‘H’ and outputs the output signals WC0 and WC1 for selecting a bit line (BL or BLB) as the write target according to write data WD. Note that the output signals WC0 and WC1 are signals that do not become ‘L’ (selected state) simultaneously.

In this example, the write driver 6 includes 2-input NAND circuits 60 and 61 and an inverter 62. The NAND circuit 60 receives an inverted signal of the write data WD and the write control signal WRITE as inputs, and outputs the output signal WC0. The NAND circuit 61 receives the write data WD and the write control signal WRITE as inputs, and outputs the output signal WC1.

### (Data Write Operation)

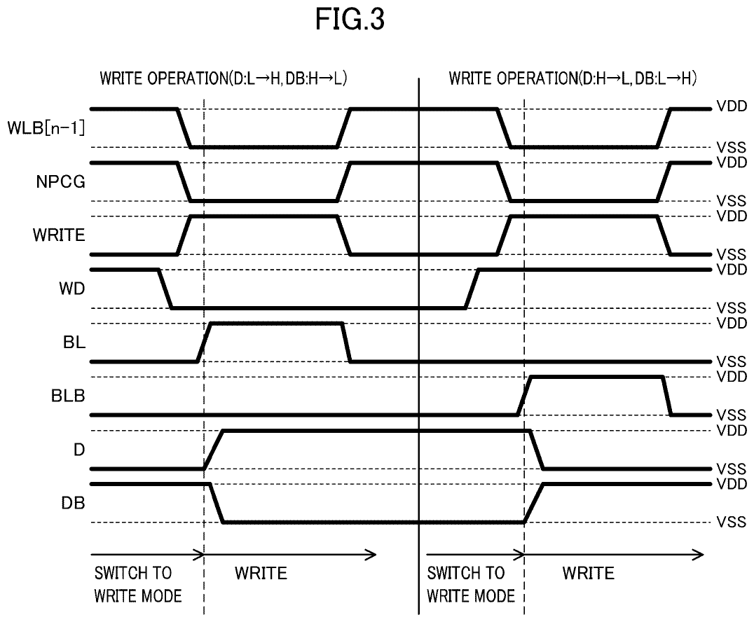

Next, referring to FIG. 3, the write operation of data into the memory cell 11 will be described. Note that, hereinafter, for convenience of description, signals may be described using only their reference characters. For example, the signal on the bit line BL may be described using only the reference character “BL”. This also applies to other signals, and also applies to alterations and other embodiments to follow.

### Operation Example 1-1

First, a write operation from D=‘L’ to ‘H’ and DB=‘H’ to ‘L’ for the memory cell 11 in the upper stage in FIG. 1 will be described (see left part of FIG. 3).

In the state before start of write operation, WLB[n−1]=NPCG=WD=‘H’. This puts the predischarge circuit 4 in the predischarge state (the transistors TN0 and TN1 are ON), whereby BL=BLB=‘L’. Also, since WRITE=‘L’, the transistors TP0 and TP1 are OFF. In the memory cell 11, the drive transistor TPM1 and the load transistor TNM0 are ON, and D=‘L’ and DB=‘H’ are held.

A switch operation to the write mode is then executed.

Specifically, with WLB[n−1]=‘L’ being set, the access transistors TPM2 and TPM3 are turned ON, permitting access from the memory cell 11 to the bit line pair BL, BLB.

With NPCG=‘L’ being set, the transistors TN0 and TN1 of the predischarge circuit 4 are turned OFF, releasing the discharge (‘L’ fixed state) of the bit line pair BL, BLB.

With WD=‘L’ and WRITE=‘H’ being set, the transistor TP0 of the column selection circuit 5 is turned ON, whereby BL=‘H’. At this time, since the transistor TP1 of the column selection circuit 5 is OFF and also the transistor TNW1 of the pulldown circuit 3 is turned ON, BLB=‘L’ is kept.

When BL=‘H’ while the access transistors TPM2 and TPM3 are ON, D is rewritten from ‘L’ to ‘H’ and DB is rewritten from ‘H’ to ‘L’. Once the write into the memory cell 11 is terminated, WLB[n−1]=‘H’ is set. This turns OFF the access transistors TPM2 and TPM3, so that D=‘H’ and DB=‘L’ are held.

### Operation Example 1-2

Next, a write operation from D=‘H’ to ‘L’ and DB=‘L’ to ‘H’ for the memory cell 11 in the upper stage in FIG. 1 will be described (see right part of FIG. 3). Description here will be made centering on differences from “Operation Example 1-1” described above.

In the switch operation to the write mode, as in Operation Example 1-1, with setting of WLB[n−1]=‘L’, the access transistors TPM2 and TPM3 are turned ON. Also, with setting of WD=‘H’ and WRITE=‘H’, the transistor TP1 of the column selection circuit 5 is turned ON, whereby BLB=‘H’ and BL=‘L’.

When BLB=‘H’ while the access transistors TPM2 and TPM3 are ON, DB is rewritten from ‘L’ to ‘H’ and D is rewritten from ‘H’ to ‘L’. Once the write into the memory cell 11 is terminated, WLB[n−1]=‘H’ is set. This turns OFF the access transistors TPM2 and TPM3, so that D=‘L’ and DB=‘H’ are held.

### —Alteration 1—

An alteration of the semiconductor memory device MD according to the first embodiment will be described. The semiconductor memory device MD of this alteration is a multi-column device.

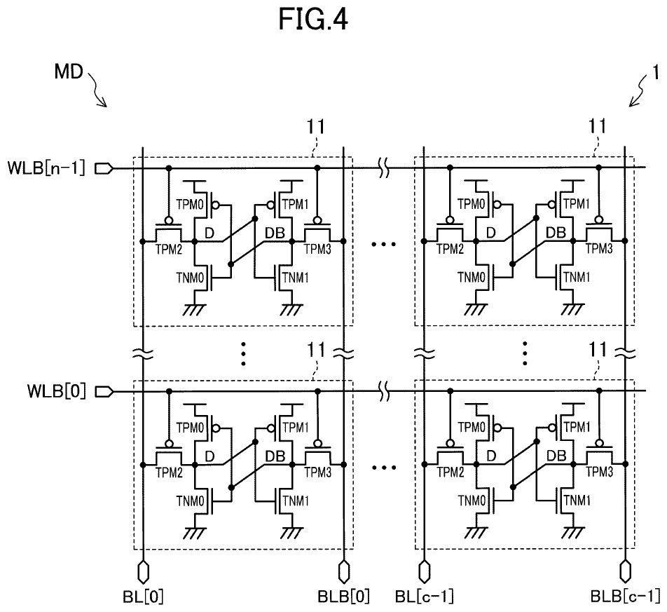

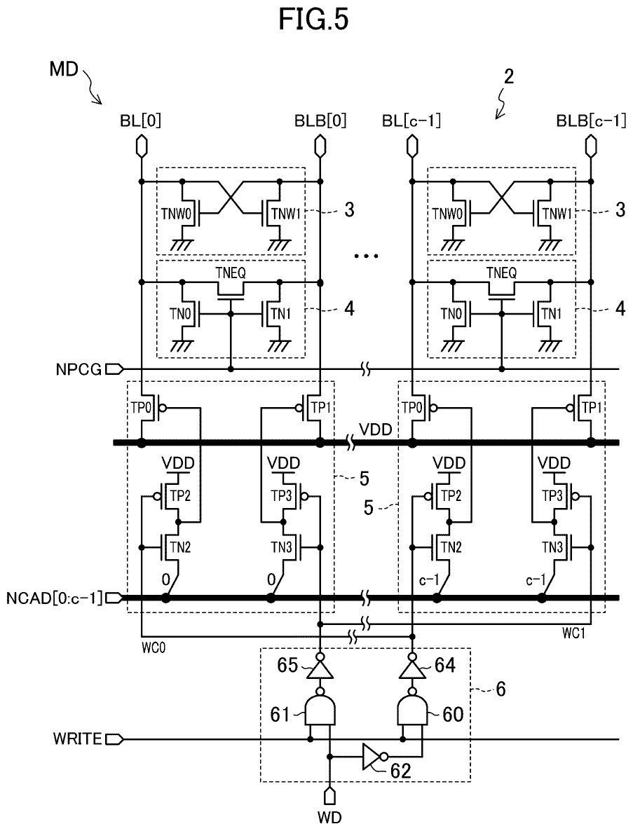

FIG. 4 is a view corresponding to FIG. 1 for this alteration, and FIG. 5 is a view corresponding to FIG. 2 for this alteration. Note that, in FIG. 4, components corresponding to those in FIG. 1 are denoted by the same reference characters. Similarly, in FIG. 5, components corresponding to those in FIG. 2 are denoted by the same reference characters. Description here will be made centering on differences from the first embodiment (single-column device).

### [Memory Cell Array]

In this alteration, the memory cell array 1 includes a plurality of memory cells 11 arranged in an array of n rows (n is a natural number)×c columns (c is a natural number)×m sets (m is a natural number). In FIG. 4, one set out of the m sets of memory cells 11 is shown.

As shown in FIG. 4, the memory cells 11 in each row are connected to a corresponding one of word lines WLB[0] to WLB[n−1]. Also, the memory cells 11 in each column are connected to a corresponding one of bit line pairs BL[0] to BL[c−1], BLB[0] to BLB[c−1]. That is, the memory cell array 1 is constituted by n word lines WLB[0] to WLB[n−1], c bit line pairs BL[0] to BL[c−1], BLB[0] to BLB[c−1], and n×c×m memory cells 11.

In the following description, as in the case of the word lines WLB, when the bit lines BL[0] to BL[c−1] are mentioned with no distinction among them, they may be referred to as the “bit lines BL” simply. This also applies to the bit lines BLB and the bit line pairs BL, BLB.

### [Write Circuit]

As shown in FIG. 5, in the write circuit 2 in this alteration, the pulldown circuit 3, the predischarge circuit 4, and the column selection circuit 5 are provided for each column. The pulldown circuit 3 and the predischarge circuit 4 are similar in configuration to those in the first embodiment (e.g., the configuration of FIG. 2).

### [Column Selection Circuit]

In this alteration, in comparison with the single-column write circuit 2 shown in FIG. 2, a bit line address signal NCAD[0:c−1] is additionally provided for selection of the write-target memory cell column. Also, with the addition of the bit line address signal NCAD[0:c−1], the configuration of the column selection circuit 5 is different from that in FIG. 2.

In this alteration, the column selection circuit 5 has a function of selecting a column that is to be the data write target, in addition to the function of selecting a bit line (BL or BLB) that is to be the write target. Specifically, data is written into the memory cell 11 connected to the bit line pair BL, BLB in the column (0 to c−1) selected according to the bit line address signal NCAD[0:c−1].

In this alteration, the column selection circuit 5 includes p-type transistors TP2 and TP3 and n-type transistors TN2 and TN3, in addition to the transistors TP0 and TP1 described above.

In the transistor TP2, the source is connected to the power supply VDD and the drain is connected to the gate of the transistor TP0. In the transistor TN2, the source is connected to the bit line address signal NCAD and the drain is connected to the gate of the transistor TP0. The output signal WC0 of the write driver 6 is given to the gates of the transistor TP2 and the transistor TN2.

In the transistor TP3, the source is connected to the power supply VDD and the drain is connected to the gate of the transistor TP1. In the transistor TN3, the source is connected to the bit line address signal NCAD and the drain is connected to the gate of the transistor TP1. The output signal WC1 of the write driver 6 is given to the gates of the transistor TP3 and the transistor TN3.

### [Write Driver]

In this alteration, in the write driver 6, an inverter 64 is provided between the NAND circuit 60 and the output node WC0, and an inverter 65 is provided between the NAND circuit 61 and the output node WC1. With this, the polarities of the output signals WC0 and WC1 are the opposite to those in the first embodiment.

### (Data Write Operation)

The data write operation in this alteration is different from that in the first embodiment in that data is written into the memory cell 11 connected to the bit line pair BL, BLB in the column selected according to the bit line address signal NCAD[0:c−1].

The other operation is similar to that described above using FIG. 3. Specifically, the switch operation from the state before start of write operation to the write mode is executed. With setting of WD=‘L’ or ‘H’ and WRITE=‘H’, the write operation into the memory cell 11 is executed. Once the write operation is terminated, WLB[n−1]=‘H’ is set, whereby the written data is held.

### Second Embodiment

A semiconductor memory device MD according to the second embodiment will be described.

The semiconductor memory device MD of this embodiment is a single-column device, and the configuration of the memory cell array 1 is the same as that in the first embodiment (e.g., the configuration of FIG. 1).

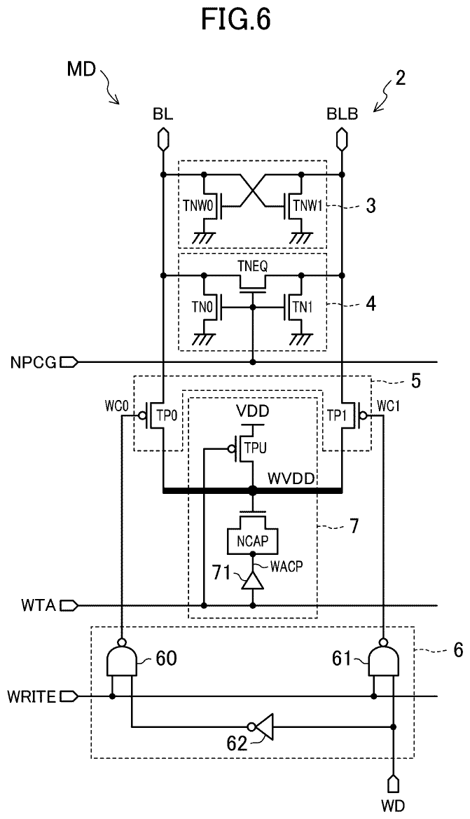

FIG. 6 is a view corresponding to FIG. 2 for this embodiment. Note that, in FIG. 6, components corresponding to those in FIG. 2 are denoted by the same reference characters. Description here will be made centering on differences from the first embodiment.

This embodiment is different from the first embodiment in that the write circuit 2 includes a voltage control circuit 7 in addition to the pulldown circuit 3, the predischarge circuit 4, the column selection circuit 5, and the write driver 6.

Also, this embodiment is different from the first embodiment in that the bit line BL is connected to an internal power supply line WVDD via the transistor TP0 and the bit line BLB is connected to the internal power supply line WVDD via the transistor TP1. In other words, the internal power supply line WVDD supplies a High-level voltage to the bit line pair BL, BLB.

### [Voltage Control Circuit]

The voltage control circuit 7 controls the voltage of the internal power supply line WVDD via a capacitor element NCAP. More specifically, the voltage control circuit 7 has a function of making the potential of the bit line (BL or BLB) on the high-potential side higher than the power supply volage VDD in response to a boost control signal WTA by the action of the capacitor element NCAP connected to the internal power supply line WVDD.

A p-type transistor TPU (corresponding to the seventh p-type transistor) that turns ON/OFF according to the boost control signal WTA is provided between the power supply VDD and the internal power supply line WVDD. In other words, the p-type transistor TPU has a function of controlling the voltage of the internal power supply line WVDD to the power supply voltage VDD.

Also, a buffer 71 that delays the boost control signal WTA is provided between the capacitor element NCAP and the boost control signal WTA. The output of the buffer 71 and the capacitor element NCAP is connected via a node WACP.

Note that, while FIG. 6 shows an example of forming the capacitor element NCAP of an n-type transistor (corresponding to the sixth n-type transistor), the capacitor element NCAP is not limited to the n-type transistor. For example, the capacitor element NCAP may be formed of a p-type transistor, or may be formed of any element other than transistors or formed of an interconnect or the like.

### (Data Write Operation)

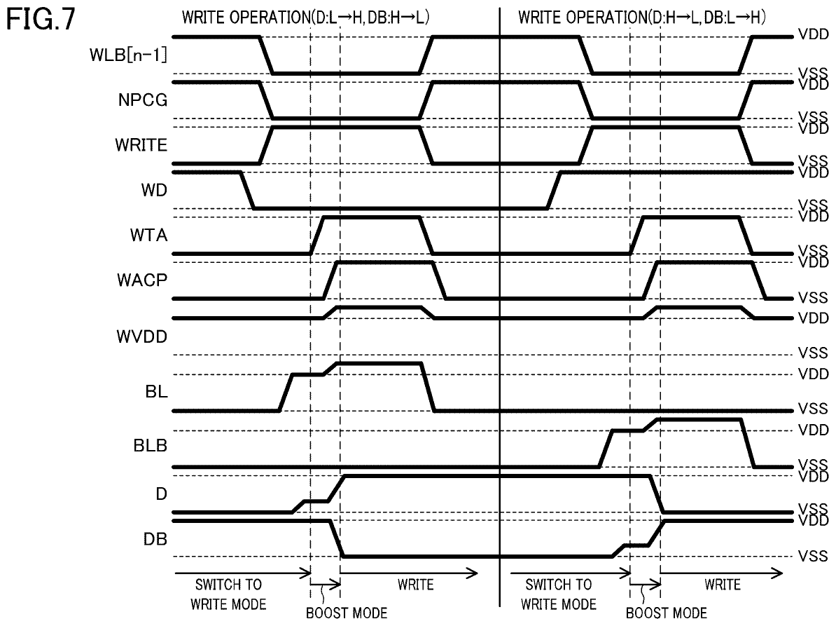

Next, referring to FIG. 7, the write operation of data into the memory cell 11 will be described. This embodiment is different from the first embodiment in that a boost mode period is provided between the switch operation to the write mode and the write operation of data into the memory cell 11. Description here will be made centering on differences from the first embodiment.

### Operation Example 2-1

First, a write operation from D=‘L’ to ‘H’ and DB=‘H’ to ‘L’ for the memory cell 11 in the upper stage in FIG. 1 will be described (see left part of FIG. 7).

As in FIG. 3, the switch operation from the state before start of write operation to the write mode is executed.

Specifically, in the switch operation to the write mode, since WTA=‘L’, the transistor TPU is ON and therefore the voltage of the internal power supply line WVDD is VDD. Also, with setting of WLB[n−1]=‘L’, NPCG=‘L’, WD=‘L’, and WRITE=‘H’, BL becomes ‘H’ and BLB remains ‘L’.

In the next boost mode operation, when WTA=‘H’ is set, the transistor TPU is turned OFF. With this, the internal power supply line WVDD and the bit line BL are shut off from the power supply VDD, entering a floating state. After a lapse of the delay time by the buffer 71 from the setting of WTA=‘H’, WACP changes from ‘L’ to ‘H’. This causes electric charge in the capacitor element NCAP to be carried to an interconnect capacitance, etc. of the internal power supply line WVDD, thereby raising the voltages of the internal power supply line WVDD and the bit line BL beyond the power supply voltage VDD. This enhances the conductance, i.e., drive capability of the access transistor TPM2, thereby increasing the current amount flowing from the bit line BL to the node D. As a result, the voltage of the node D becomes higher than that in the configuration of the first embodiment.

Thereafter, when the potential of D rises up to the threshold of the load transistor TNM1, the load transistor TNM1 turns ON, causing DB to be rewritten from ‘H’ to ‘L’. Also, since the drive transistor TPM0 turns ON, D is rewritten from ‘L’ to ‘H’. Once the write into the memory cell 11 is terminated, WLB[n−1]=‘H’ is set. This turns OFF the access transistors TPM2 and TPM3, so that D=‘H’ and DB=‘L’ are held.

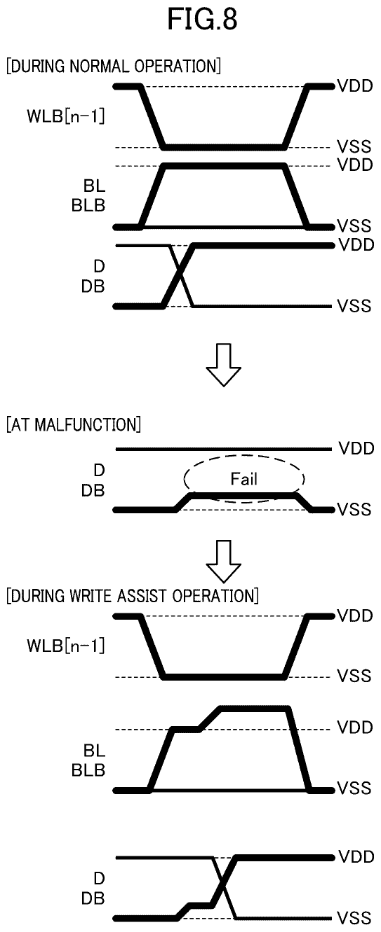

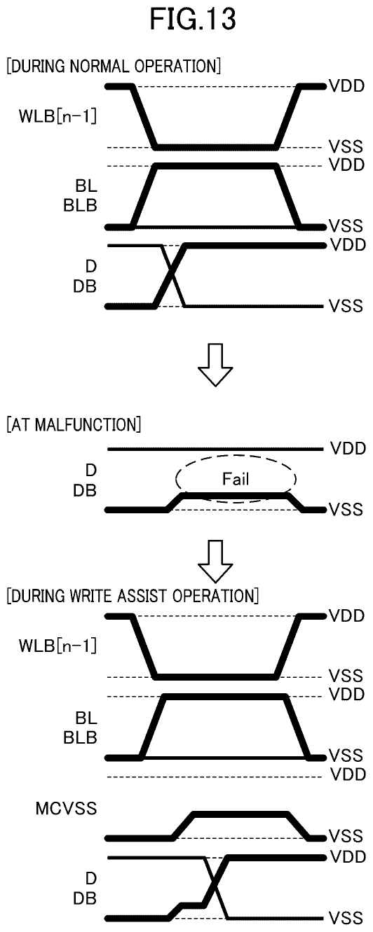

The effect obtained by providing the voltage control circuit 7 in this embodiment will be described in detail with reference to FIG. 8. In FIG. 8, BL is indicated by the bold line and BLB by the narrow line. Also, D is indicated by the bold line and DB by the narrow line. This also applies to the case in FIG. 13 to be described later.

First, in the case where the conductance of the access transistor TPM2 is set to be sufficiently high, the memory cell 11 operates with no trouble as described in the first embodiment (see “During normal operation” in FIG. 8).

On the other hand, in the case where the conductance (drive capability) of the access transistor TPM2 is relatively low, while the access transistor TPM2 is turned ON, it fails to secure a sufficient amount of current flowing from the bit line BL to the node D. As a result, the voltage of D may fail to rise up to the threshold voltage of the load transistor TNM1, causing the load transistor TNM1 to fail to turn ON. In this case, it is not possible to rewrite D from ‘L’ to ‘H’ and rewrite DB from ‘H’ to ‘L’ (see “At malfunction” in FIG. 8).

In the above case, by providing the voltage control circuit 7, the conductance, i.e., drive capability of the access transistor TPM2 can be enhanced. This increases the current amount flowing from the bit line BL to the node D, and makes the voltage of the node D high compared with the case of not providing the voltage control circuit 7, thereby making the load transistor TNM1 turn ON easily. In other words, by providing the voltage control circuit 7, the write into the memory cell 11 is assisted, whereby normal write can be achieved (see “During write assist operation” in FIG. 8).

### Operation Example 2-2

Next, a write operation from D=‘H’ to ‘L’ and DB=‘L’ to ‘H’ for the memory cell 11 in the upper stage in FIG. 1 will be described (see right part of FIG. 7). Description here will be made centering on differences from “Operation Example 2-1” described above.

In the switch operation to the write mode, as in Operation Example 2-1, since WTA=‘L’, the transistor TPU is ON and therefore the voltage of the internal power supply line WVDD is VDD. Also, with setting of WD=‘H’ in addition to the setting of WLB[n−1]=‘L’, NPCG=‘L’, and WRITE=‘H’, BLB becomes ‘H’ and BL remains ‘L’.

In the next boost mode operation, when WTA=‘H’ is set, the transistor TPU is turned OFF. With this, the internal power supply line WVDD and the bit line BLB are shut off from the power supply VDD, entering a floating state. After a lapse of the delay time by the buffer 71 from the setting of WTA=‘H’, WACP changes from ‘L’ to ‘H’. This causes electric charge in the capacitor element NCAP to be carried to an interconnect capacitance, etc. of the internal power supply line WVDD, thereby raising the voltages of the internal power supply line WVDD and the bit line BLB beyond the power supply voltage VDD. This enhances the conductance, i.e., drive capability of the access transistor TPM3, thereby increasing the current amount flowing from the bit line BLB to the node DB. As a result, the voltage of the node DB becomes higher than that in the configuration of the first embodiment.

Thereafter, when the potential of DB rises up to the threshold of the load transistor TNM0, the load transistor TNM0 turns ON, causing D to be rewritten from ‘H’ to ‘L’. Also, since the drive transistor TPM1 turns ON, DB is rewritten from ‘L’ to ‘H’. Once the write into the memory cell 11 is terminated, WLB[n−1]=‘H’ is set. This turns OFF the access transistors TPM2 and TPM3, so that D=‘L’ and DB=‘H’ are held.

### —Alteration 2—

An alteration of the semiconductor memory device MD according to the second embodiment will be described.

The semiconductor memory device MD of this alteration is a multi-column device, and the configuration of the memory cell array 1 is the same as that in Alteration 1 of the first embodiment (e.g., the configuration of FIG. 4).

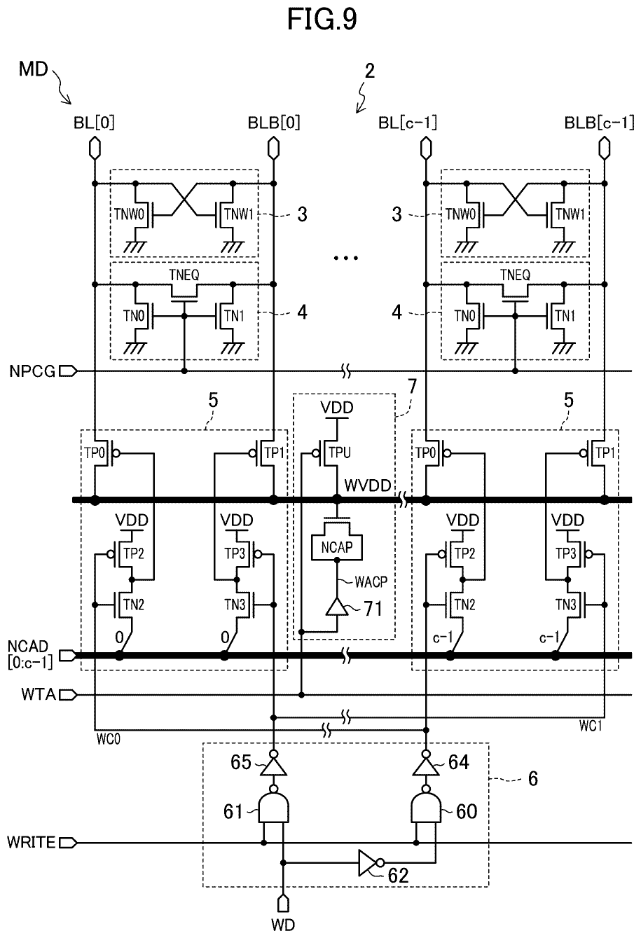

FIG. 9 is a view corresponding to FIG. 6 for this alteration. Note that, in FIG. 9, components corresponding to those in FIG. 6 are denoted by the same reference characters. Description here will be made centering on differences from the second embodiment (single-column device).

### [Write Circuit]

As shown in FIG. 9, in the write circuit 2 in this alteration, the pulldown circuit 3, the predischarge circuit 4, and the column selection circuit 5 are provided for each column. The pulldown circuit 3 and the predischarge circuit 4 are similar to those in the second embodiment (e.g., the configurations in FIG. 6).

### [Column Selection Circuit]

In this alteration, in comparison with the single-column write circuit 2 shown in FIG. 6, a bit line address signal NCAD[0:c−1] is additionally provided for selection of the write-target memory cell column. Also, with the addition of the bit line address signal NCAD[0:c−1], the configuration of the column selection circuit 5 is changed. The configuration shown in FIG. 9 is the same as that of the column selection circuit 5 in Alteration 1 of the first embodiment (see FIG. 5) and has similar functions. That is, the column selection circuit 5 has a function of selecting a column that is to be the data write target among the plurality of columns, in addition to the function of selecting a bit line (BL or BLB) as the write target.

### [Write Driver]

In this alteration, in the write driver 6, an inverter 64 is provided between the NAND circuit 60 and the output node WC0, and an inverter 65 is provided between the NAND circuit 61 and the output node WC1. With this, the polarities of the output signals WC0 and WC1 are the opposite to those in the second embodiment.

### (Data Write Operation)

The data write operation in this alteration is different from that in the second embodiment in that data is written into the memory cell 11 connected to the bit line pair BL, BLB in the column (0 to c−1) selected according to the bit line address signal NCAD[0:c−1].

The other operation is similar to that described above using FIG. 7. That is, the switch operation from the state before start of write operation to the write mode is executed, and after the operation in the boost mode, write into the memory cell 11 is executed. Once the write is terminated, WLB[n−1]=‘H’ is set, whereby the written data is held.

### Third Embodiment

A semiconductor memory device MD according to the third embodiment will be described. The semiconductor memory device MD of this embodiment is a single-column device.

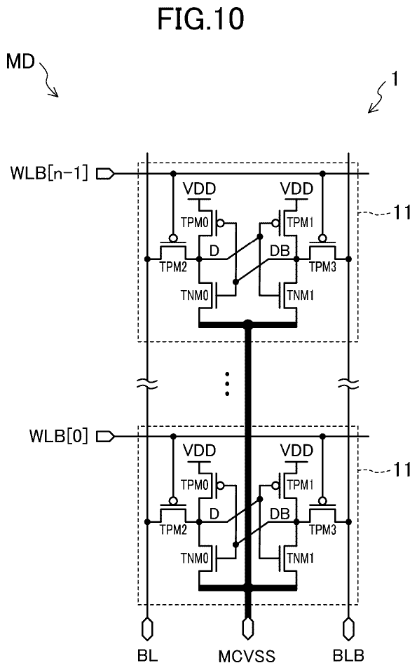

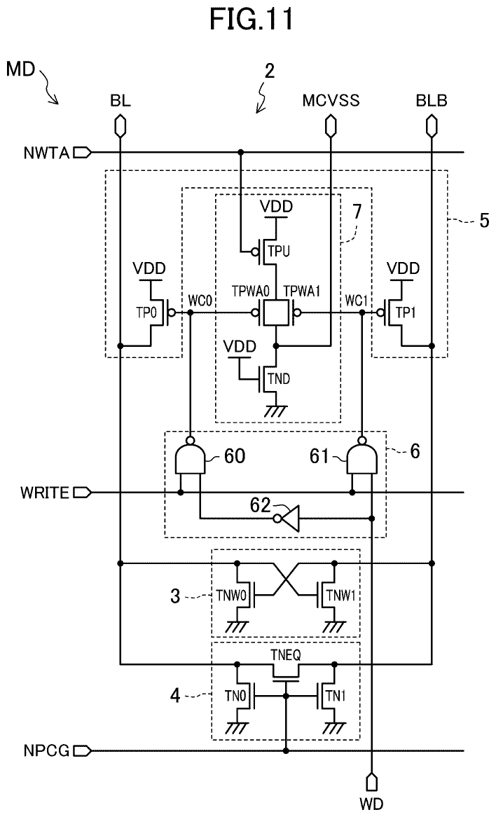

FIG. 10 is a view corresponding to FIG. 1 for this embodiment, and FIG. 11 is a view corresponding to FIG. 6 for this embodiment. Note that, in FIG. 10, components corresponding to those in FIG. 1 are denoted by the same reference characters. Also, in FIG. 11, components corresponding to those in FIG. 6 are denoted by the same reference characters. Description here will be made centering on differences from the above-described embodiments (particularly, the second embodiment).

As shown in FIG. 10, this embodiment is different from the first and second embodiments in that the sources of the load transistors TNM0 and TNM1 are connected to a common internal ground line MCVSS (corresponding to the internal power supply line). The voltage of the internal ground line MCVSS is controlled by the write circuit 2.

In this embodiment, also, as shown in FIG. 11, the configuration of the voltage control circuit 7 is different from that in the second embodiment.

### [Voltage Control Circuit]

The voltage control circuit 7 controls the voltage of the internal ground line MCVSS connected to the memory cell 11. Also, the voltage control circuit 7 is configured to make the potential of the internal ground line MCVSS higher than the ground VSS at the time of write into the memory cell.

The voltage control circuit 7 includes p-type transistors TPU, TPWA0, and TPWA1 and an n-type transistor TND.

In the transistor TPU, the source is connected to the power supply VDD, the drain is connected to the sources of the transistors TPWA0 and TPWA1, and a boost control signal NWTA is given to the gate. The boost control signal NWTA is a polarity-reversed signal of the boost control signal WTA in the second embodiment.

The transistors TPWA0 and TPWA1 are mutually connected at their sources and at their drains. The output WC0 of the write driver 6 is connected to the gate of the transistor TPWA0, and the output WC1 of the write driver 6 is connected to the gate of the transistor TPWA1.

In the transistor TND (corresponding to the fifth n-type transistor), the gate is connected to the power supply VDD, the source is connected to the ground VSS, and the drain is connected to the internal ground line MCVSS and the drains of the transistors TPWA0 and TPWA1.

### (Data Write Operation)

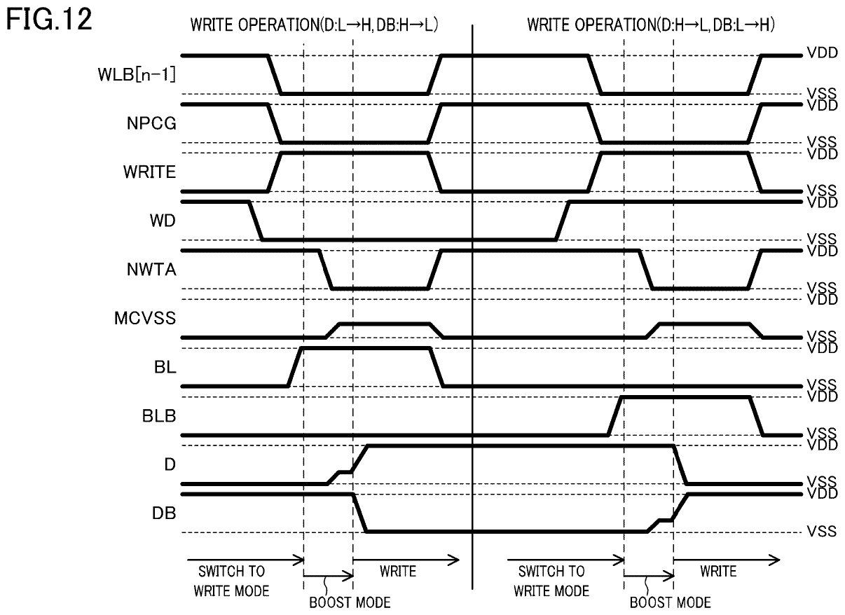

Next, referring to FIG. 12, the write operation of data to the memory cell 11 will be described. Description here will be made centering on differences from the second embodiment (see FIG. 7).

### Operation Example 3-1

First, a write operation from D=‘L’ to ‘H’ and DB=‘H’ to ‘L’ for the memory cell 11 in the upper stage in FIG. 10 will be described (see left part of FIG. 12).

As in FIG. 7, the switch operation from the state before start of write operation to the write mode is executed.

Specifically, in the switch operation to the write mode, since NWTA=‘H’, the transistor TPU is OFF. Since the transistor TND is ON, the voltage of the internal ground line MCVSS is VSS.

With setting of WD=‘L’ and WRITE=‘H’, the transistor TP0 is turned ON, and this makes BL=‘H’. At this time, since the transistor TP1 is turned OFF and the transistor TNW1 of the pulldown circuit 3 is ON, BLB=‘L’.

In the next boost mode, when NWTA=‘L’ is set, the transistor TPU is turned ON, and the transistor TPWA0 is ON. With this, the voltage of the internal ground line MCVSS becomes a divided voltage of the ON resistances of the transistor TPU, the transistor TPWA0, and the transistor TND, rising from the ground potential VSS. This reduces the conductance, i.e., drive capability of the load transistor TNM0. As a result, the voltage of the node D becomes high compared with the case of not providing the voltage control circuit 7 (e.g., the first embodiment).

Thereafter, when the potential of D rises up to the threshold of the load transistor TNM1, the load transistor TNM1 turns ON, causing DB to be rewritten from ‘H’ to ‘L’. Also, since the drive transistor TPM0 turns ON, D is rewritten from ‘L’ to ‘H’. Once the write into the memory cell 11 is terminated, WLB[n−1]=‘H’ is set. This turns OFF the access transistors TPM2 and TPM3, so that D=‘H’ and DB=‘L’ are held.

The effect obtained by providing the voltage control circuit 7 in this embodiment will be described with reference to FIG. 13.

First, in the case where the conductance of the access transistor TPM2 is set to be sufficiently high, the memory cell 11 operates with no trouble as described in the first embodiment (see “During normal operation” in FIG. 13).

On the other hand, in the case where the conductance (drive capability) of the access transistor TPM2 is relatively low, while the access transistor TPM2 is turned ON, it fails to secure a sufficient amount of current flowing from the bit line BL to the node D. As a result, the voltage of D may fail to rise up to the threshold voltage of the load transistor TNM1, causing the load transistor TNM1 to fail to turn ON. In this case, it is not possible to rewrite D from ‘L’ to ‘H’ and rewrite DB from ‘H’ to ‘L’ (see “At malfunction” in FIG. 13).

In the above case, by providing the voltage control circuit 7, to raise the internal ground line MCVSS, i.e., the source voltage of the load transistor TNM0, the voltage of the node D becomes high compared with the case of not providing the voltage control circuit 7. This makes the load transistor TNM1 turn ON easily. In other words, by providing the voltage control circuit 7, the write into the memory cell 11 is assisted, whereby normal write can be achieved (see “During write assist operation” in FIG. 13).

### Operation Example 3-2

Next, a write operation from D=‘H’ to ‘L’ and DB=‘L’ to ‘H’ for the memory cell 11 in the upper stage in FIG. 10 will be described (see right part of FIG. 12). Description here will be made centering on differences from the “Operation Example 3-1” described above.

In the switch operation to the write mode, as in Operation Example 3-1, since NWTA=‘H’, the transistor TPU is OFF. Since the transistor TND is ON, the voltage of the internal ground line MCVSS is VSS.

With setting of WD=‘H’ and WRITE=‘H’, the transistor TP1 is turned ON, and this makes BLB=‘H’. At this time, since the transistor TP0 is turned OFF and the transistor TNW0 of the pulldown circuit 3 is ON, BL=‘L’.

In the next boost mode, when NWTA=‘L’ is set, the transistor TPU is turned ON, and the transistor TPWA1 is ON. With this, the voltage of the internal ground line MCVSS becomes a divided voltage of the ON resistances of the transistor TPU, the transistor TPWA1, and the transistor TND, rising from the ground potential VSS. This reduces the conductance, i.e., drive capability of the load transistor TNM1. As a result, the voltage of the node DB becomes high compared with the case of not providing the voltage control circuit 7 (e.g., the first embodiment).

Thereafter, when the potential of DB rises up to the threshold of the load transistor TNM0, the load transistor TNM0 turns ON, causing D to be rewritten from ‘H’ to ‘L’. Also, since the drive transistor TPM1 turns ON, DB is rewritten from ‘L’ to ‘H’. Once the write into the memory cell 11 is terminated, WLB[n−1]=‘H’ is set. This turns OFF the access transistors TPM2 and TPM3, so that D=‘L’ and DB=‘H’ are held.

### —Alteration 3—

An alteration of the semiconductor memory device MD according to the third embodiment will be described.

The semiconductor memory device MD of this alteration is a multi-column device.

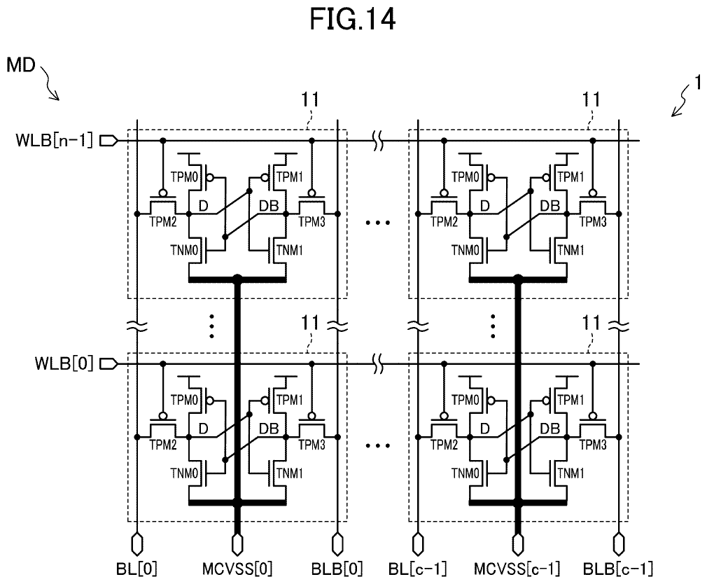

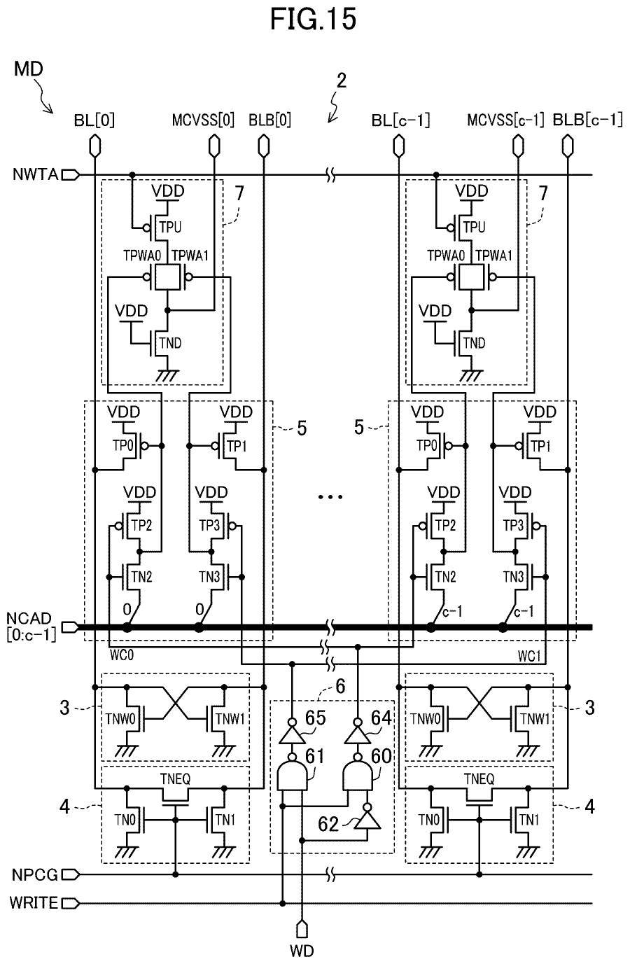

FIG. 14 is a view corresponding to FIG. 10 for this alteration, and FIG. 15 is a view corresponding to FIG. 11 for this alteration. Note that, in FIG. 14, components corresponding to those in FIG. 10 are denoted by the same reference characters. Also, in FIG. 15, components corresponding to those in FIG. 11 are denoted by the same reference characters. Description here will be made centering on differences from the third embodiment (single-column device) and the alteration (multi-column device) of the second embodiment.

### [Memory Cell Array]

In this alteration, the memory cell array 1 includes a plurality of memory cells 11 arranged in an array of n rows (n is a natural number)×c columns (c is a natural number)×m sets (m is a natural number). In FIG. 14, one set out of the m sets of memory cells 11 is shown.

As shown in FIG. 14, the memory cells 11 in each column are connected to a corresponding one of bit line pairs BL[0] to BL[c−1], BLB[0] to BLB[c−1] and a corresponding one of internal ground lines MCVSS [0] to MCVSS[c−1]. For example, the memory cells in the 0-th column are connected to the common bit line pair BL[0], BLB[0] and the common internal ground line MCVSS [0]. This also applies to the 1st to (c−1)th columns.

### [Write Circuit]

As shown in FIG. 15, in the write circuit 2 in this alteration, the pulldown circuit 3, the predischarge circuit 4, the column selection circuit 5, and the voltage control circuit 7 are provided for each column. The pulldown circuit 3, the predischarge circuit 4, and the write driver 6 are similar to those in the alteration of the second embodiment (e.g., the configuration of FIG. 9).

### [Column Selection Circuit]

In this alteration, in comparison with the single-column write circuit 2 shown in FIG. 11, a bit line address signal NCAD[0:c−1] is additionally provided for selection of the write-target memory cell column. Also, with the addition of the bit line address signal NCAD[0:c−1], the configuration of the column selection circuit 5 is changed. The configuration shown in FIG. 15 is roughly the same as that of the column selection circuit 5 in Alteration 2 of the second embodiment and has similar functions. That is, in this alteration, also, the column selection circuit 5 has a function of selecting a column that is to be the data write target among the plurality of columns, in addition to the function of selecting a bit line (BL or BLB) as the write target.

Also, in this alteration, the gates of the transistor TP0 and the transistor TPWA0 provided in the same column are mutually connected, and the gates of the transistor TP1 and the transistor TPWA1 provided in the same column are mutually connected.

The configuration of the voltage control circuit 7 shown in FIG. 15 is similar to that in the third embodiment (see FIG. 11) and has similar functions.

### (Data Write Operation)

The data write operation in this alteration is different from that in the third embodiment in that data is written into the memory cell 11 connected to the bit line pair BL, BLB in the column (0 to c−1) selected according to the bit line address signal NCAD[0:c−1].

The other operation is similar to that described above using FIG. 12. That is, the switch operation from the state before start of write operation to the write mode is executed, and after the operation in the boost mode, write into the memory cell 11 is executed. Once the write is terminated, WLB[n−1]=‘H’ is set, whereby the written data is held.

Note that the technique in the present disclosure is applicable, not only to the configurations described in the above embodiments, but also to embodiments appropriately subjected to changes, replacements, additions, and omissions from the above embodiments. Also, the components described in the above embodiments can be combined appropriately to provide a new embodiment.

According to the present disclosure, a peripheral circuit of an SRAM using an SRAM cell that uses a p-type transistor for an access transistor can be provided. The present disclosure is therefore very useful.

1. A semiconductor memory device comprising memory cells and a write circuit,
wherein
each of the memory cells includes
a first p-type transistor having a gate connected to a first node, a source connected to a first power supply, and a drain connected to a second node,
a first n-type transistor having a gate connected to the first node, a source connected to a second power supply, and a drain connected to the second node,
a second p-type transistor having a gate connected to the second node, a source connected to the first power supply, and a drain connected to the first node,
a second n-type transistor having a gate connected to the second node, a source connected to the second power supply, and a drain connected to the first node,
a third p-type transistor provided between the second node and a first bit line, and having a gate connected to a word line, and
a fourth p-type transistor provided between the first node and a second bit line, and having a gate connected to the word line, and
the write circuit includes
a column selection circuit including a fifth p-type transistor provided between the first bit line and the first power supply and a sixth p-type transistor provided between the second bit line and the first power supply, and
a predischarge circuit including a third n-type transistor provided between the first bit line and the second power supply and a fourth n-type transistor provided between the second bit line and the second power supply.

2. The semiconductor memory device of claim 1, wherein
the predischarge circuit includes a fifth n-type transistor provided between the first bit line and the second bit line.

3. The semiconductor memory device of claim 1, comprising
a memory cell array constituted by a plurality of columns, each column including a unit of the memory cells connected to the common first bit line and the common second bit line,
wherein
the column selection circuit is configured to operate the fifth p-type transistor and/or the sixth p-type transistor of a column selected as a data write target out of the plurality of columns.

4. A semiconductor memory device comprising memory cells and a write circuit,
wherein
each of the memory cells includes
a first p-type transistor having a gate connected to a first node, a source connected to a first power supply, and a drain connected to a second node,
a first n-type transistor having a gate connected to the first node, a source connected to a second power supply, and a drain connected to the second node,
a second p-type transistor having a gate connected to the second node, a source connected to the first power supply, and a drain connected to the first node,
a second n-type transistor having a gate connected to the second node, a source connected to the second power supply, and a drain connected to the first node,
a third p-type transistor provided between the second node and a first bit line, and having a gate connected to a word line, and
a fourth p-type transistor provided between the first node and a second bit line, and having a gate connected to the word line, and
the write circuit includes
a column selection circuit including a fifth p-type transistor provided between the first bit line and an internal power supply line and a sixth p-type transistor provided between the second bit line and the internal power supply line,
a predischarge circuit including a third n-type transistor provided between the first bit line and the second power supply and a fourth n-type transistor provided between the second bit line and the second power supply, and
a voltage control circuit including a seventh p-type transistor provided between the first power supply and the internal power supply line and a capacitor element configured to make the internal power supply line higher in potential than the first power supply at the time of write into the memory cell.

5. The semiconductor memory device of claim 4, wherein
the predischarge circuit includes a fifth n-type transistor provided between the first bit line and the second bit line.

6. The semiconductor memory device of claim 4, wherein
the capacitor element is formed of a sixth n-type transistor.

7. The semiconductor memory device of claim 4, comprising
a memory cell array constituted by a plurality of columns, each column including a unit of the memory cells connected to the common first bit line and the common second bit line,
wherein
the column selection circuit is configured to operate the fifth p-type transistor and/or the sixth p-type transistor of a column selected as a data write target out of the plurality of columns.

8. A semiconductor memory device comprising memory cells and a write circuit,
wherein
each of the memory cells includes
a first p-type transistor having a gate connected to a first node, a source connected to a first power supply, and a drain connected to a second node,
a first n-type transistor having a gate connected to the first node, a source connected to an internal power supply line, and a drain connected to the second node,
a second p-type transistor having a gate connected to the second node, a source connected to the first power supply, and a drain connected to the first node,
a second n-type transistor having a gate connected to the second node, a source connected to the internal power supply line, and a drain connected to the first node,
a third p-type transistor provided between the second node and a first bit line, and having a gate connected to a word line, and
a fourth p-type transistor provided between the first node and a second bit line, and having a gate connected to the word line, and
the write circuit includes
a column selection circuit including a fifth p-type transistor provided between the first bit line and the first power supply and a sixth p-type transistor provided between the second bit line and the first power supply,
a predischarge circuit including a third n-type transistor provided between the first bit line and the second power supply and a fourth n-type transistor provided between the second bit line and the second power supply, and
a voltage control circuit including a fifth n-type transistor provided between the second power supply and the internal power supply line and a seventh p-type transistor configured to make the internal power supply line higher in potential than the second power supply at the time of write into the memory cell.

9. The semiconductor memory device of claim 8, wherein
the predischarge circuit includes a sixth n-type transistor provided between the first bit line and the second bit line.

10. The semiconductor memory device of claim 8, comprising
a memory cell array constituted by a plurality of columns, each column including a unit of the memory cells connected to the common first bit line and the common second bit line,
wherein
the column selection circuit is configured to operate the fifth p-type transistor and/or the sixth p-type transistor of a column selected as a data write target out of the plurality of columns.
